(19) United States
(12) Patent Application Publication
(10) Pub. No.: US 2024/0309553 A1
(43) Pub. Date: Sep. 19, 2024

(54) METHODS OF FORMING AN OXIDE USING VAN DER WAALS MATERIALS

(71) Applicant: Regents of the University of Minnesota, Minneapolis, MN (US)

(72) Inventors: Bharat Jalan, Minneapolis, MN (US); Hyojin Yoon, Minneapolis, MN (US); Sooho Choo, Minneapolis, MN (US)

(73) Assignee: Regents of the University of Minnesota, (US)

(21) Appl. No.: 18/605,241

(22) Filed: Mar. 14, 2024

Related U.S. Application Data
(60) Provisional application No. 63/452,109, filed on Mar. 14, 2023.

(51) Int. Cl. C30B 25/18; C01B 32/188; C01G 23/00; C30B 29/32

(52) U.S. Cl. CPC C30B 25/18; C01B 32/188; C01G 23/006; C30B 29/32

(57) ABSTRACT

The present document relates to methods of forming an oxide material using van der Waals materials. Compositions and structures including such an oxide material are also described herein.

### CROSS-REFERENCE TO RELATED APPLICATION

This application claims the benefit of U.S. Provisional Patent Application No. 63/452,109, filed on Mar. 14, 2023, which is incorporated by reference herein in its entirety.

### STATEMENT OF GOVERNMENT SUPPORT

This invention was made with government support under DE-SC0020211 awarded by the U.S. Department of Energy, and FA9550-21-1-0460, FA9550-21-1-0025, and FA9550-18-1-0294 awarded by the Other Agency. The government has certain rights in the invention.

### FIELD

The present document relates to methods of forming an oxide using van der Waals materials. In some cases, such methods can employ remote epitaxy. Compositions and structures including such an oxide are also described herein.

### BACKGROUND

Metal-containing oxides can possess useful properties, such as a high dielectric constant, ferroelectricity, and superconductivity. Yet, effective growth of oxide thin films can be limited to the use of certain substrates having particular crystal structure and lattice parameters, such that growth on arbitrary and yet other useful materials can be challenging.

### SUMMARY

The present document relates to methods of forming an oxide (e.g., a perovskite oxide) using van der Waals materials. In some embodiments, the oxide includes a metal-containing oxide. In some embodiments, the oxide includes one or more of an alkali metal, an alkaline earth metal, a transition metal, a post-transition metal, a metalloid, a lanthanide, or a combination of any of these.

In one aspect, this document features a method of forming an oxide film. In some embodiments, the method can include: providing a first substrate comprising a van der Waals material disposed on a top surface of said first substrate; and delivering a pre-oxidized precursor to a surface of said van der Waals material, thereby forming said oxide film.

In another aspect, this document features a method of forming an oxide film. In some embodiments, the method can include: providing a first substrate comprising a van der Waals material disposed on a top surface of said first substrate; delivering a pre-oxidized precursor to a surface of said van der Waals material, thereby forming said oxide film; exfoliating said oxide film, or a portion thereof, from said van der Waals material and said first substrate; and transferring the exfoliated oxide film, or a portion thereof, to a top surface of a second substrate.

In another aspect, this document features a method of forming an oxide (e.g., a perovskite oxide). The method can include: providing a first substrate comprising a van der Waals material disposed on a top surface of said first substrate; and delivering a non-oxidized precursor and a pre-oxidized precursor to a surface of said van der Waals material, thereby forming the oxide.

In another aspect, this document features a method of forming an oxide (e.g., a perovskite oxide). The method can include: providing a first substrate comprising a van der Waals material disposed on a top surface of said first substrate; and delivering a metal precursor and a pre-oxidized precursor to a surface of said van der Waals material, thereby forming the oxide. In some cases, the van der Waals material is not a monolayer of graphene. In some cases, said pre-oxidized precursor comprises an organic moiety. In some cases, said pre-oxidized precursor comprises one or more of an alkali metal, an alkaline earth metal, a transition metal, a post-transition metal, a metalloid, a lanthanide, or a combination of any of these.

In another aspect, this document features a method of forming an oxide film (e.g., a perovskite oxide film). The method can include: providing a first substrate comprising a van der Waals material disposed on a top surface of said first substrate; delivering a metal precursor and a pre-oxidized precursor to a surface of said van der Waals material, thereby forming the oxide film; exfoliating said oxide film, or a portion thereof, from said van der Waals material and said first substrate; and transferring the exfoliated oxide film, or a portion thereof, to a top surface of a second substrate.

In some cases, said non-oxidized precursor comprises a metal precursor. In some cases, the non-oxidized precursor comprises one or more of an alkali metal, an alkaline earth metal, a transition metal, a post-transition metal, a metalloid, a lanthanide, or a combination of any of these.

In any cases herein, the metal precursor comprises an alkali metal, an alkaline earth metal, a transition metal, a post-transition metal, a metalloid, a lanthanide, or a combination of any of these. In some cases, the metal precursor comprises an alkali metal, an alkaline earth metal, or a combination of any of these.

In any cases herein, the pre-oxidized precursor comprises an organic moiety. In some cases, the pre-oxidized precursor comprises one or more of an alkali metal, an alkaline earth metal, a transition metal, a post-transition metal, a metalloid, a lanthanide, or a combination of any of these. In some cases, the pre-oxidized precursor comprises one or more of a transition metal, a post-transition metal, a metalloid, a lanthanide, or a combination of any of these.

The first substrate can include a material for deposition of the oxide (e.g., the perovskite oxide). In some cases, the first substrate comprises a single crystal substrate and/or an oxide substrate. Non-limiting examples of materials for a first substrate includes strontium titanium oxide (STO) or lanthanum-strontium aluminum tantalate (LSAT), lanthanum aluminate (LAO), and strontium lanthanum aluminate (SLAO).

The van der Waals material can be disposed on a surface of a substrate. In some cases, said van der Waals material comprises a monolayer or a multilayer (e.g., a bilayer). In some cases, said van der Waals material comprises a bilayer of graphene. Non-limiting examples of van der Waals materials include graphene, hexagonal boron nitride (h-BN), molybdenum disulfide (MoS₂), molybdenum diselenide (MoSe₂), tungsten disulfide (WS₂), or amorphous graphene.

Metal precursors can be employed, including a first metal precursor to provide a first metal in combination with a second metal precursor to provide a second metal. In some cases, said first metal precursor comprises an alkali metal or an alkaline earth metal (e.g., Mg, Ca, Sr, Ba, K, Rb, or a combination of any of these). In some cases, said second metal precursor comprises a transition metal, a post-transition metal, a metalloid, a lanthanide, or a combination of any of these (e.g., any described herein).

A precursor can be pre-oxidized (e.g., including one or more oxygen atoms). In some cases, said pre-oxidized precursor comprises a transition metal (e.g., Sc, Ti, V, Cr, Mn, Fe, Co, Ni, Cu, Zn, Y, Zr, Nb, Mo, Ru, Rh, Pd, Ag, Cd, Hf, Ta, W, Re, Os, Ir, Pt, Au, or a combination of any of these), a post-transition metal (e.g., Sn, Al, Ga, In, Tl, Pb, Bi, or a combination of any of these), a metalloid (e.g., B, Ge, Si, As, Sb, Te, or a combination of any of these), a lanthanide (e.g., La, Ce, Pr, Nd, Sm, Eu, Gd, Tb, Dy, Ho, Er, Tm, Yb, Lu, or a combination of any of these), or a combination of any of these. The pre-oxidized precursor can include a metal organic precursor. In some cases, the pre-oxidized precursor further comprises at least one organic ligand of R or OR, wherein R is an organic moiety (e.g., optionally substituted aliphatic).

A precursor can be non-oxidized (e.g., not including one or more oxygen atoms). In some cases, said non-oxidized precursor comprises a transition metal (e.g., Sc, Ti, V, Cr, Mn, Fe, Co, Ni, Cu, Zn, Y, Zr, Nb, Mo, Ru, Rh, Pd, Ag, Cd, Hf, Ta, W, Re, Os, Ir, Pt, Au, or a combination of any of these), a post-transition metal (e.g., Sn, Al, Ga, In, Tl, Pb, Bi, or a combination of any of these), a metalloid (e.g., B, Ge, Si, As, Sb, Te, or a combination of any of these), a lanthanide (e.g., La, Ce, Pr, Nd, Sm, Eu, Gd, Tb, Dy, Ho, Er, Tm, Yb, Lu, or a combination of any of these), or a combination of any of these. In some embodiments, the non-oxidized precursor comprises hydrogen, halo, aliphatic, etc. The non-oxidized precursor can include a metal organic precursor.

In some cases, said delivering is conducted in the absence of an oxygen source (e.g., molecular oxygen, ozone, or oxygen plasma). In some cases, said delivering is conducted in the absence of plasma (e.g., oxygen plasma). In some cases, said delivering is conducted in the presence of an oxygen source (e.g., molecular oxygen, ozone, or oxygen plasma).

In some cases, the oxide can be provided as a perovskite.

The oxide can be provided as a film (e.g., a thin film) or a nanomembrane. In some cases, said film or said nanomembrane comprises a thickness of about 1 nm to about 1 micron. In some cases, said film or said nanomembrane comprises a single crystalline film. In some cases, said film or said nanomembrane comprises a film with high mobility (e.g., a mobility greater than about 10,000 or 30,000 cm²V⁻¹s⁻¹ at a low temperature, such as about 1.8 K), high dielectric constant (e.g., a dielectric constant greater than about 20,000 or 24,000 at a low temperature, such as about 2K), high thermal conductivity (e.g., a thermal conductivity of greater than about 10 Wm⁻¹K⁻¹ at 100 K), ferroelectricity, multiferroicity, and/or superconductivity.

The method can include further operations. In some case, the method can include: exfoliating said oxide, or a portion thereof, from said van der Waals material and said first substrate; transferring the exfoliated oxide, or a portion thereof, to a top surface of a second substrate; and optionally annealing or treating the transferred oxide, or a portion thereof. The second substrate can include any useful material. In some cases, said second substrate comprises an oxide substrate, a dielectric substrate, a flexible substrate, or a carrier substrate.

In another aspect, this document features a structure comprising: an oxide film disposed on a top surface of a first substrate; and an interlayer comprising a van der Waals material disposed between said film and said substrate. In some cases, said van der Waals material is not a monolayer of graphene. The structure can be formed from any method described herein. In some embodiments, the oxide film is a metal-containing oxide film. In some embodiments, the oxide film includes one or more of an alkali metal, an alkaline earth metal, a transition metal, a post-transition metal, a metalloid, a lanthanide, or a combination of any of these.

In another aspect, one aspect of this document features a free-standing structure comprising: an oxide film disposed on a top surface of a foreign substrate, wherein said foreign substrate is similar or different than a substrate used to form the film. The free-standing structure can be formed from any method described herein. In some embodiments, the oxide film is a metal-containing oxide film. In some embodiments, the oxide film includes one or more of an alkali metal, an alkaline earth metal, a transition metal, a post-transition metal, a metalloid, a lanthanide, or a combination of any of these.

### Definitions

As used herein, the term “about” means+/−10% of any recited value. As used herein, this term modifies any recited value, range of values, or endpoints of one or more ranges.

By “micro” is meant having at least one dimension that is less than 1 mm and, optionally, equal to or larger than about 1 μm. For instance and without limitation, a microstructure (e.g., any structure described herein) can have a length, width, height, cross-sectional dimension, circumference, radius (e.g., external or internal radius), or diameter that is equal to or larger than about 1 μm and less than 1 mm.

By “nano” is meant having at least one dimension that is less than 1 μm but equal to or larger than about 0.1 nm. For instance and without limitation, a nanostructure (e.g., any structure described herein) can have a length, width, height, cross-sectional dimension, circumference, radius (e.g., external or internal radius), or diameter that is equal to or larger than about 0.1 nm less than 1 μm.

As used herein, the terms “top,” “bottom,” “upper,” “lower,” “above,” and “below” are used to provide a relative relationship between structures. The use of these terms does not indicate or require that a particular structure must be located at a particular location in the apparatus.

Unless otherwise defined, all technical and scientific terms used herein have the same meaning as commonly understood by one of ordinary skill in the art to which this invention pertains. Although methods and materials similar or equivalent to those described herein can be used to practice the invention, suitable methods and materials are described below. All publications, patent applications, patents, and other references mentioned herein are incorporated by reference in their entirety. In case of conflict, the present specification, including definitions, will control. In addition, the materials, methods, and examples are illustrative only and not intended to be limiting.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1A-1B provides non-limiting schematics showing a comparison of growth techniques for oxides on graphene, including conventional oxide MBE (FIG. 1A) and hybrid MBE modified by excluding oxygen (FIG. 1B). Without wishing to be limited by mechanism or theory, use of a gentle oxidation environment in some instances may avoid graphene damage. Alternatively, an oxidation environment may be provided to an extent to avoid graphene damage, while also being used to control stoichiometry (e.g., oxygen content) of an oxide.

FIG. 2 provides a non-limiting schematic showing summary of graphene growth and the wet transfer process. 1) Graphene (Gr) is synthesized on the surface of polycrystalline copper (Cu) foil using chemical vapor deposition. (2) Polymethyl methacrylate resist (PMMA 950 C4) is spin-coated on top of the copper foil and baked on a hot plot at 180° C. for 15 minutes. (3) The bottom-side graphene is removed using oxygen plasma. (4) The copper foil is suspended on top of a copper etchant solution using surface tension until all copper is etched away. (5) The remaining graphene is extracted from the copper etchant using a glass slide and suspended on the surface of deionized (DI) water for cleaning. (6) The cleaned graphene is scooped onto the oxide substrate using a flow-mesh. (7) The graphene-scooped oxide substrate is heated to 65° C. until dry. (8) The excess graphene is removed by cutting with a razor. (9) After removing the flow mesh, the sample is further baked at 180° C. for 15 minutes. (10) The baked sample is placed in acetone until all the PMMA is dissolved away. (11) The monolayer graphene-transferred oxide substrate sample is finally rinsed in acetone and isopropyl alcohol (IPA). If bilayer graphene is desired, the process is repeated once more using a monolayer graphene-transferred oxide substrate.

FIG. 3A-3D shows non-limiting surface structure of wet-transferred graphene. Provided are structure schematics, reflection high-energy electron diffraction (RHEED) patterns, and atomic force microscopy (AFM) images of ML-Gr/SrTiO₃(001) (FIG. 3A), BL-Gr/SrTiO₃(001) (FIG. 3B), ML-Gr/LSAT(001) (FIG. 3C), and BL-Gr/LSAT(001) (FIG. 3D). The RHEED patterns show the characteristic pattern of polycrystalline graphene, and the AFM images show residual PMMA from the graphene wet-transfer process. ML-Gr indicates monolayer graphene, and BL-Gr indicates bilayer graphene.

FIG. 4A-4D shows a non-limiting example of hybrid MBE of SrTiO₃ without oxygen. Provided are a schematic of the grown film structure SrTiO₃/SrTiO₃(001) (FIG. 4A), a graph showing the intensity of RHEED spots versus time during growth (FIG. 4B), and high-resolution X-ray diffraction (HRXRD) 2θ-ω coupled scans and AFM (inset) of the resulting film (FIG. 4B). Also provided is a graph showing the lattice parameter (aₒₒₚ) as a function of the TTIP:Sr beam equivalent pressure (BEP) ratio during growth, which indicates the presence of a MBE growth window (FIG. 4D).

FIG. 5A-5D shows a non-limiting demonstration of epitaxy for perovskites on graphene using hybrid MBE. Provided are sample schematics, RHEED images, HRXRD 2θ-ω coupled scans, and reciprocal space maps (RSMs) of SrTiO₃/SrTiO₃(001) (FIG. 5A), SrTiO₃/ML-Gr/SrTiO₃(001) (FIG. 5B), SrTiO₃/BL-Gr/SrTiO₃(001) (FIG. 5C), and SrTiO₃/ML-Gr/LSAT(001) (FIG. 5D).

FIG. 6A-6D shows a non-limiting demonstration of cracked films grown on monolayer graphene (ML-Gr). Provided are optical micrographs and confocal Raman micrographs of ML-Gr/SrTiO₃(001) before growth (FIG. 6A), the resulting SrTiO₃/ML-Gr/SrTiO₃(001) after growth (FIG. 6B), ML-Gr/LSAT(001) before growth (FIG. 6C), and the resulting SrTiO₃/ML-Gr/LSAT(001) after growth (FIG. 6D). All confocal Raman micrographs are rastered over the sample surface. The comparison of the micrographs shows that both the oxide films and the graphene crack during growth.

FIG. 7A-7D shows a non-limiting demonstration of hybrid MBE-grown film exfoliation. Provided are confocal Raman spectroscopy and microscopy of BL-Gr/SrTiO₃(001) before growth (FIG. 7A), the resulting SrTiO₃/BL-Gr/SrTiO₃(001) after growth (FIG. 7B), and the restored BL-Gr/SrTiO₃(001) via exfoliating the grown film (FIG. 7C). Each Raman micrograph shows the integrated intensity from one graphene peak scanned over the surface of the sample. Also provided are HRXRD 2θ-ω coupled scans of the sample before growth, and after growth, exfoliation, and then transfer to an r-plane Al₂O₃ substrate (FIG. 7D).

FIG. 8A-8B shows a non-limiting example of graphene left on the STO substrate after exfoliation of the grown STO film. Provided are AFM image of graphene/STO substrate after the film was exfoliated (FIG. 8A) and a set of the Raman spectra of 49 different points on graphene left on the substrate, showing G (dashed line on the left) and 2D (dashed line on the right) peaks from graphene (FIG. 8B). The inset is a schematic image of the sample with scan numbers showing the positions where each Raman spectrum was measured. The size of the sample was 5×5 mm.

FIG. 9 shows a non-limiting example of a perovskite film exfoliation and transfer process. (1) PMMA 950 C4 resist is spin-coated onto Kapton tape adhered to a glass microscope slide for support. (2) The oxide film grown on bilayer graphene is gently placed on top, and air bubbles between the oxide film and the PMMA resist are removed by pressing on the substrate with a cotton swab. (3) The sample is heated to 180° C. for 15 minutes to evaporate the chlorobenzene solvent from the PMMA resist. (4) The oxide film is exfoliated from the substrate by attaching Kapton tape to the back of the substrate and pulling on the tape. (5) The exfoliated oxide film is placed on the foreign substrate under the weight of the glass slide, and then submerged in acetone. (6) After the PMMA has dissolved away, the tape and glass slide are withdrawn. The remaining transferred oxide membrane is finally withdrawn and rinsed in fresh acetone and IPA.

FIG. 10 shows a non-limiting examples of rocking curve progression of SrTiO₃ thin film during exfoliation. The line labeled as “(i)” is ‘after growth’ (FWHM=0.032°). The line labeled as “(ii)” is ‘after exfoliation’ (FWHM=2.388°). The line labeled as “(iii)” is ‘after transfer’ (FWHM=0.415°). The line labeled as “(iv)” is ‘after O₂ annealing at 1050° C.’ (FWHM=0.372°).

FIG. 11A-11B shows non-limiting examples of high-resolution imaging of cube-on-cube epitaxy. Provided are drift-corrected scanning transmission electron microscopy high-angle annular dark field (STEM-HAADF) (FIG. 11A) and medium-angle annular dark field (MAADF) (FIG. 11B) images, indicating a [100] (001)//[100] (001) orientation relationship.

FIG. 12 shows non-limiting examples of scanning transmission electron microscopy (STEM) characterization of pre-transfer SrTiO₃. Provided are an overview of a large film region containing pristine and defective graphene (panel labeled “A”); STEM-HAADF images and energy-dispersive X-ray spectroscopy (STEM-EDS) composition maps for the pristine graphene regions (panels labeled “B” or “C”) and defective graphene regions (panels labeled “D” or “E”). Also provided are STEM-HAADF images of the regions around the graphene defect, showing that the image labeled as “F” shows a [110] (001)//[100] (001) epitaxial relationship, while the film in the image labeled as “G” is rotated slightly in-plane near the defect.

FIG. 13A-13C shows non-limiting examples of high-resolution imaging of graphene layers. Provided are drift-corrected STEM-HAADF (FIG. 13A), MAADF (FIG. 13B), and BF (FIG. 13C) images, showing the presence and variation of ˜3 graphene layers with an inter-layer spacing of ˜3.8 Å.

FIG. 14 shows non-limiting examples of determinations of graphene thickness. Provided are Raman spectra of 22 different points on graphene transferred onto SiO₂/Si substrate. The inset is the intensity ratio of each point, I_{2D}/I_{G}=1.70˜2.65, suggesting nearly monolayer thickness of the transferred graphene layer. Note that the SrTiO₃ substrate was not used for this analysis because of the overlap of SrTiO₃ and graphene signals at G peak position. Note that the graphene synthesized on the copper foil is a monolayer, and the monolayer graphene was transferred twice to form bilayer graphene on the SrTiO₃ substrates.

FIG. 15 shows non-limiting examples of STEM characterization of transferred SrTiO₃ on r-Al₂O₃. Provided is a scanning transmission electron microscopy image of a SrTiO₃ epitaxial nanomembrane transferred to a foreign r-plane Al₂O₃ substrate, which includes a STEM-HAADF image (labeled as “A”) and STEM-EDS elemental maps (labeled as “B”, “C”, “D”, and “E”) of the same region. The dark square region indicates a potential void in the film. Lattice vectors are given relative to the R3̅c (r-Al₂O₃) and Pm3̅m (STO) space groups, respectively.

FIG. 16 shows non-limiting examples of square defects before and after transfer. Provided are STEM-HAADF images of the film before transfer (upper images, panels labeled as “A”) and after transfer (lower images, panels labeled as “B”), showing that the density of defects (indicated by the white arrows) is not uniform and appears lower in the as-grown film (1 defect over 500 nm) than the transferred film (8-10 defects over 500 nm). Defects in the film after transfer are clustered. Cracking in the film after growth (panels labeled as “B”) was a result of exfoliation and transfer process.

FIG. 17 shows results from HRXRD 2θ-ω coupled scans of BaTiO₃ (BTO) films grown with oxygen plasma (labeled with “(i)”) and without oxygen plasma (labeled with “(ii)”) for films before exfoliation (upper graph) and after exfoliation (lower graph).

FIG. 18A-18F shows characterization of BTO films grown with oxygen plasma and without oxygen plasma. Provided are AFM images (FIG. 18A), Raman spectra (FIG. 18B), and optical microscopy images (FIG. 18C) of as-grown BTO films grown with oxygen plasma, as well as AFM images (FIG. 18D), Raman spectra (FIG. 18E), and optical microscopy images (FIG. 18F) of as-grown BTO films without oxygen plasma.

FIG. 19 shows HRXRD scans of BTO membranes films grown with oxygen plasma (labeled with “(i)”) and without oxygen plasma (labeled with “(ii)”).

FIG. 20 shows rocking curves of BTO films grown with oxygen plasma (labeled with or “(iii)”) and without oxygen plasma (labeled with “(ii)” or “(iv)”) before exfoliation (upper curves) and after exfoliation (lower curves).

### DETAILED DESCRIPTION

The present document describes the use of van der Waals materials to provide oxides. In some cases, the oxide has a formula of AₘOₙ, wherein each of m and n is, independently, an integer from 1 to 5 (e.g., from 1 to 4, 1 to 3, 1 to 2, 2 to 5, 2 to 4, or 2 to 3), and wherein A is one or more of an alkali metal, an alkaline earth metal, a transition metal, a post-transition metal, a metalloid, a lanthanide, or a combination of any of these.

In some cases, the oxide is a perovskite oxide having a formula of ABO₃, in which each of A and B is, independently, a cation, a metalloid, or a metal (e.g., a metal cation). In some cases, the perovskite oxide can include a doped form thereof (e.g., including a dopant selected from another cation or metal that is different than that present in ABO₃). Non-limiting examples of dopants can include any metal or cation described herein. In some cases, A and/or B is one or more of an alkali metal, an alkaline earth metal, a transition metal, a post-transition metal, a metalloid, a lanthanide, or a combination of any of these.

Perovskite oxides with a chemical formula of ABO₃ can possess desired properties, such as high dielectric constant, ferroelectricity, and superconductivity. Such properties can be used to develop electronic devices. One consideration in the growth of perovskite oxide thin films is that films are typically grown on limited substrates that have similar crystal structures and lattice parameters to the film. This limitation can prevent perovskite oxides from being used with other material systems, such as the use of a flexible substrate that in turn can be used in flexible electronics. Various methods to detach a grown film from the substrate and transfer them onto arbitrary substrates have been suggested to integrate perovskite oxides' properties into other materials systems. Non-limiting example of perovskite oxides include a metal titanate, such as strontium titanate (SrTiO₃), barium strontium titanate (BaSrTiO₃), barium titanate (e.g., BaTiO₃), or calcium titanate (e.g., CaTiO₃). Other examples of perovskite oxides can include any that can be formed using precursors described herein. Yet other examples of perovskite oxides include those having any combination of alkali metals, alkaline metals, transition metals, post-transition metals, metalloids, and/or lanthanides described herein.

Remote epitaxy relates to epitaxial growth of crystalline materials on substrates covered with van der Waals materials, which is referred to herein also as two-dimensional (2D) materials. Non-limiting 2D materials include, without limitation, graphene, amorphous graphene, hexagonal boron nitride (h-BN), molybdenum disulfide (MoS₂), molybdenum diselenide (MoSe₂), and tungsten disulfide (WS₂). In some cases, a 2D material can be characterized as having out-of-plane van der Waals bonds and/or weak dangling bonds. The weak out-of-plane interaction of the 2D material allows the electrostatic potential of the substrate to propagate through the 2D material, leading to epitaxial growth. In addition, mechanical separation (or exfoliation) of the grown film from the substrate covered with the 2D material is possible because the grown film is only bound by weak van der Waals bonds, thereby providing freestanding oxides. Remote epitaxy can be achieved for materials as long as the substrate has sufficient electrostatic potential to penetrate the 2D material. Remote epitaxy can, therefore, be employed to grow oxides with sufficiently high ionicity.

In addition to providing freestanding oxides, remote epitaxy can lower the misfit dislocation density in heteroepitaxy, in which the growing film and substrate are composed of different materials. Because the grown film does not have strong chemical bonds with the substrate, the strain is relaxed spontaneously on the 2D material before the film thickness reaches a critical thickness.

Remote epitaxy growth of oxides using a substrate with a 2D material (e.g., a graphene layer) can be used to improve structural quality and obtaining freestanding epitaxial nanomembranes for scientific study, applications, and economical reuse of substrates. However, the aggressive oxidizing conditions typically used in growing epitaxial oxides can damage 2D materials. As described herein, hybrid molecular beam epitaxy (HMBE) can be used to grow oxide layers, while avoiding oxidizing conditions that can damage 2D materials. For example, growth of SrTiO₃ on graphene is described, in which HMBE does not require an independent oxygen source, thus avoiding graphene damage. Rather, HMBE uses a pre-oxidized precursor (e.g., a pre-oxidized metal precursor) in combination with another metal precursor. The pre-oxidized precursor can include any useful metal or metalloid (e.g., a transition metal, a post-transition metal, a metalloid, a lanthanide, or a combination of any of these, as well as others described herein). This approach produces epitaxial films with self-regulating cation stoichiometry.

As described herein, the epitaxial growth of functional oxides using a substrate with a graphene layer (or other 2D material layer) can be used to improve structural quality and/or obtain free-standing epitaxial nano-membranes for scientific study, applications, and economical reuse of substrates. However, the aggressive oxidizing conditions that can be employed in growing epitaxial oxides can damage 2D materials. Here, hybrid molecular beam epitaxy was used for oxide growth that does not require an independent oxygen source, thus avoiding graphene damage. Yet, in some embodiments, hybrid molecular beam epitaxy can be conducted in the presence of oxygen and/or plasma, and the underlying van der Waals material remains undamaged, such as the deposited layer can be exfoliated from the underlying van der Waals material and substrate.

In some cases, the film (e.g., being about 50 nm thick) can be exfoliated and transferred to a secondary substrate (or a foreign substrate). Such methods can provide free-standing oxide nano-membranes grown in an adsorption-controlled manner by hybrid molecular beam epitaxy. In some cases, the film can be formed on a first substrate (e.g., a single crystal substrate, such as SrTiO₃ (001) or LSAT (001)), and then transferred to a secondary substrate (e.g., a flexible substrate, a dielectric substrate, a carrier substrate, etc.). This approach has potential implications for the commercial application of oxides (e.g., perovskite oxides) in flexible electronics and as a dielectric in van der Waals thin-film electronics.

The film can be characterized in any useful manner. In some cases, the film comprises a single crystalline film. In some cases, the film comprises a nanomembrane (e.g., having a thickness from about 1 nm to about 1 micron). In some cases, the film is characterized by high mobility, high dielectric constant, high thermal conductivity, ferroelectricity, multiferroicity, and/or superconductivity.

### Methods

The present document encompasses methods of forming an oxide (e.g., a perovskite oxide). Such methods can include providing a substrate and delivering one or more precursors (e.g., any described herein) to a surface of the substrate. In some cases, the substrate can include a van der Waals material disposed on a top surface of the substrate. Any useful substrate can be employed, such as a single crystal substrate, an oxide substrate, etc.

The van der Waals material can include any such material described herein in any form (e.g., as a layer, including a monolayer or a multilayer, such as a bilayer). The van der Waals material can be provided on the first substrate in any useful manner, such as by physical vapor deposition (PVD), chemical vapor deposition (CVD), plasma enhanced CVD (PE-CVD), low pressure CVD (LP-CVD), atomic layer deposition (ALD), plasma enhanced ALD (PE-ALD), sputter deposition, electron-beam deposition, etc. In some cases, the deposited van der Waals material can be used directly. Alternatively, the deposited van der Waals material can be transferred (e.g., by way of etching, dissolving, or removing an initial substrate) to a further substrate by any useful process (e.g., a dry process, a wet process, or a combination thereof).

The precursors and conditions for delivery of such precursors can be selected to provide a desired, stoichiometric layer including the metals present in the precursor. In some cases, the precursor can include one or more oxygen atoms, thereby providing sufficient oxygen atoms for forming an oxide (e.g., a perovskite oxide). In some cases, the precursor (e.g., the pre-oxidized precursor having a metal organic moiety) can be selected to be volatile during deposition or delivery. In some cases, the metal(s) within the one or more precursors can be selected to provide a material having a perovskite structure.

Any useful combination of precursors can be employed. In some cases, a pre-oxidized precursor is employed to provide an oxide film. In some cases, a pre-oxidized precursor is employed without another precursor. In some cases, a pre-oxidized precursor is employed to with another precursor (e.g., a metal precursor, a non-oxidized precursor, or others described herein) provide an oxide film. In some cases, a non-oxidized precursor is employed to provide an oxide film. In some cases, a non-oxidized precursor is employed with oxygen plasma to provide an oxide film.

During delivery of the one or more precursors, any useful reaction condition can be maintained. Without wishing to be limited by mechanism or theory, the use of pre-oxidizing precursors can provide a deposition environment that minimizes damage to a van der Waals material. In some cases, the use of oxygen, plasma, or other harsh conditions is avoided. Yet, in some cases, oxygen and/or oxygen plasma may be used, in combination with pre-oxidized precursor(s), to further modify the stoichiometry of the deposited oxide material. In this way, conditions for providing oxygen and/or oxygen plasma need not provide all of the oxygen atoms needed for a desired stoichiometry but may be used to fine-tune such stoichiometry in combination with the oxygen atoms provided by the pre-oxidized precursor(s).

After formation, the oxide can be exfoliated and transferred. In some cases, exfoliation can include removing the oxide, or a portion thereof, from the first substrate employed during deposition of the material. In some cases, exfoliation can include removing the oxide from the van der Waals material, which in turn can remain attached to a surface of the first substrate. Exfoliation can include a dry process, a wet process, or a combination thereof (e.g., wet etching, dry etching, mechanical exfoliation, spalling, heating, etc.).

In turn, the exfoliated oxide can be transferred to a surface of a second substrate. Transfer processes can include the use of one or more support layers that can be reversibly or temporarily attached to a first surface of the oxide material, such that the opposing (second) surface of the oxide material can be contacted with the second substrate. Support layers can be formed of any material that can be attached and then removed. Non-limiting materials for support layers include a polymer, an epoxy, a photoresist, a substrate, or a combination of any of these. Optionally, the support layer can be attached by use of an adhesion layer, which can include an adhesive, a tape, a polymer, a photoresist, and the like. Removal of the adhesion layer and/or support layers can include wet processes, dry processes, or a combination thereof (e.g., etching, peeling, heating, solubilizing, or a combination of any of these). When an adhesion layer is present, removal of the adhesion layer can result in detachment, and thus removal, of the support layers. The second substrate can include any useful structure (e.g., a heterostructure) or material (e.g., oxide, dielectric, conductor, polymer, or a combination thereof). In some cases, the second substrate is a flexible substrate or a carrier substrate.

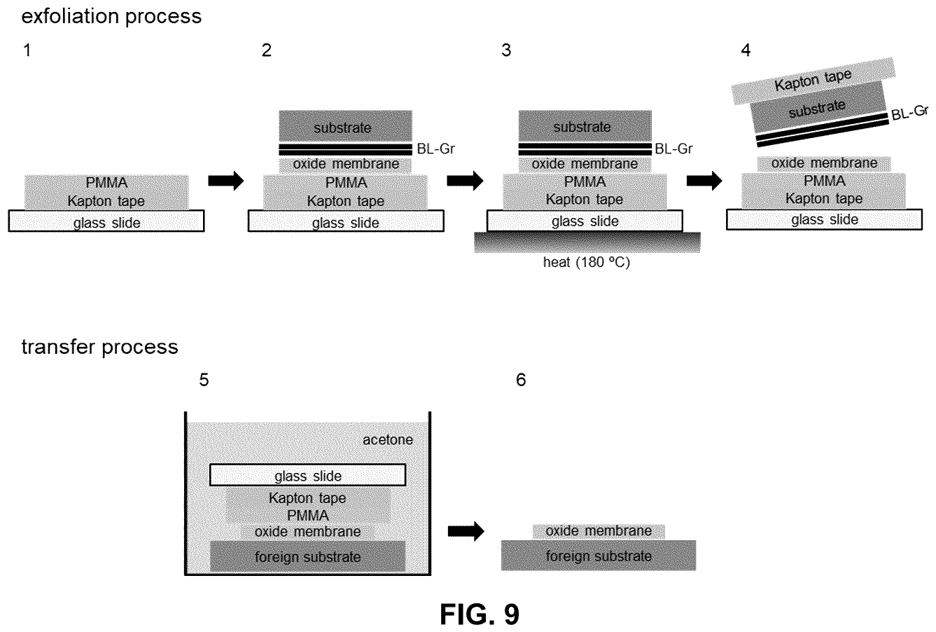

In some cases, the oxide (after exfoliation and/or transfer) can retain the structural properties that are determined after deposition of the material. That is, in some cases, the steps of exfoliation and transfer do not damage the oxide material. Non-limiting methods for exfoliation and transfer are described herein, e.g., in FIG. 9.

The film can be further treated. In some cases, the film can be annealed (e.g., in the presence of oxygen, hydrogen, an inert gas, vacuum, high pressure, or a combination of any of these), doped, plasma treated, oxidized, coated, or a combination of any of these.

### Precursors

Any useful precursor can be employed to form an oxide material. Such precursors can include one or more metal precursors, metalloid precursors, pre-oxidized precursors, non-oxidized precursors, or combinations thereof.

Metal precursors can be employed, including a metal precursor include an alkali metal, an alkaline earth metal, a transition metal, a post-transition metal, a lanthanide, or a combination of any of these (e.g., any described herein). A metal precursor can be pre-oxidized to include one or more oxygen atoms or can be non-oxidized to not include oxygen atom(s).

Metalloid precursors can be employed, including a metalloid precursor include one or more metalloids (e.g., any described herein). A metalloid precursor can be pre-oxidized to include one or more oxygen atoms or can be non-oxidized to not include oxygen atom(s).

A precursor can be pre-oxidized (e.g., including one or more oxygen atoms). In some cases, said pre-oxidized precursor can include an alkali metal, an alkaline earth metal, a transition metal, a post-transition metal, a metalloid, a lanthanide, or a combination of any of these (e.g., any described herein). A pre-oxidized precursor can include any ligand described herein (e.g., a ligand including one or more oxygen atoms).

A precursor can be non-oxidized (e.g., not including one or more oxygen atoms). In some cases, said non-oxidized precursor can include an alkali metal, an alkaline earth metal, a transition metal, a post-transition metal, a metalloid, a lanthanide, or a combination of any of these (e.g., any described herein). A non-oxidized precursor can include any ligand described herein (e.g., a ligand that does not include one or more oxygen atoms).

In some cases, one or more precursors can be used to form an oxide (e.g., a perovskite oxide). In some cases, a combination of precursors is employed, including a first precursor comprising A, and a second precursor comprising BLₓ, in which each of A and B is, independently, a cation, a metalloid, or a metal; each L is, independently, a ligand (e.g., halo or an organic moiety, such as any described herein); and x is an integer from 1 to 5.

In some cases, a precursor includes A. In some cases, a precursor includes BLₓ, in which each of A and B is, independently, a cation, a metalloid, or a metal; each L is, independently, a ligand (e.g., H, halo, or an organic moiety, such as any described herein); and x is an integer from 1 to 5.

In some cases, at least one L includes an oxygen atom (e.g., in the form of hydroxyl (e.g., —OH) or alkoxy (e.g., —OR, wherein R is an organic moiety). In some cases, the use of a precursor that is a metal-organic precursor with oxygen can provide sufficient oxygen condition to grow oxides without damage to a van der Waals material, thereby enabling exfoliation and transfer of the grown films.

In some cases, the precursor (e.g., a metal precursor, a metal-organic precursor, a metalloid precursor, or a metalloid-organic precursor) is a volatile precursor. In some cases, the use of a volatile precursor can provide self-regulating cation stoichiometry for oxides formed on van der Waals materials.

In some cases, at least one L is OR, wherein R is an organic moiety. In some cases, each L is, independently, OR, wherein R is an organic moiety. In some cases, the precursor comprises B(OR)ₓ, wherein B is a cation, a metalloid, or a metal (e.g., a transition metal, a post-transition metal, a lanthanide, such as any described herein), R is an organic moiety, and x is an integer from 1 to 5.

In some cases, at least one L includes an oxygen atom (e.g., in the form of hydroxyl (e.g., —OH) or alkoxy (e.g., —OR, wherein R is an organic moiety).

In some cases, at least one L does not include an oxygen atom (e.g., as in H, halo, nitro, alkyl, aliphatic (e.g., —R, wherein R is an organic moiety).

Non-limiting examples of organic moieties (e.g., for L or R) include an optionally substituted aliphatic. As used herein, aliphatic is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof (e.g., cycloaliphatic), and further including straight- and branched-chain arrangements, and all stereo and position isomers as well. Non-limiting substitutions for aliphatic groups can include, e.g., halo (e.g., F, Cl, Br, or I), haloalkyl (e.g., halomethyl, haloethyl, or halopropyl, which can include one or more halo substitutions), amino (e.g., —NR^{N1}R^{N2}, where each of R^{N1} and R^{N2} is, independently, H, alkyl, or haloalkyl), hydroxyl, and alkoxy. In some cases, any alkyl herein can include a C₁₋₃, C₁₋₆, C₁₋₁₂, C₁₋₁₆, C₁₋₁₈, C₁₋₂₀, or C₁₋₂₄ alkyl group.

In some cases, at least one L is a multidentate (e.g., bidentate) ligand. In some cases, every L is a multidentate (e.g., bidentate) ligand. In some cases, the precursor comprises BLₓ, wherein B is a cation, a metalloid, or a metal (e.g., a transition metal, a post-transition metal, or a lanthanide, such as any described herein), L is a multidentate ligand, and x is an integer from 1 to 5. In some cases, the multidentate ligand comprises one or more oxygen atoms.

Non-limiting examples of multidentate ligands include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular cases, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In some cases, alkylene can include any multivalent (e.g., bivalent) form of an alkyl group described herein. In some cases, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group.

In some cases, heteroalkylene can include any alkylene described herein having one, two, three, or four non-carbon heteroatoms (e.g., independently selected from the group consisting of nitrogen, oxygen, phosphorous, sulfur, selenium, or halo).

In some cases, aryl can include any group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like.

In some cases, arylene can include any multivalent (e.g., bivalent) form of an aryl group described herein.

In some cases, heterocyclyl can include a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo).

The multidentate ligand can be unsubstituted or substituted. In some cases, the multidentate ligand includes one or more oxygen atoms. Such oxygen atoms can be present in any useful manner, such as an oxy group (—O—), an oxo group (═O), a hydroxyl group (—OH), or a combination of any of these.

In some cases, A is an alkali metal or an alkaline earth metal. Non-limiting examples include magnesium (Mg), calcium (Ca), strontium (Sr), barium (Ba), potassium (K), rubidium (Rb), or a combination of any of these. In some cases, A or B is a transition metal. Non-limiting examples include
scandium (Sc), titanium (Ti), vanadium (V), chromium (Cr), manganese (Mg), iron (Fe), cobalt (Co), nickel (Ni), copper (Cu), zinc (Zn), yttrium (Y), zirconium (Zr), niobium (Nb), molybdenum (Mo), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), or a combination of any of these. In some cases, A or B is a post-transition metal. Non-limiting examples include tin (Sn), aluminum (Al), gallium (Ga), indium (In), thallium (Tl), lead (Pb), bismuth (Bi), or a combination of any of these. In some cases, A or B is a metalloid. Non-limiting examples include boron (B), germanium (Ge), silicon (Si), arsenic (As), antimony (Sb), tellurium (Te), or a combination of any of these. In some cases, A or B is a lanthanide. Non-limiting examples include lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), or a combination of any of these). Non-limiting examples of precursors include titanium(IV) isopropoxide (TTIP, Ti[OCH(CH₃)₂]₄), titanium(IV) ethoxide (Ti[OCHCH₃]₄), titanium tetradimethylaminopropanol (Ti[DMAP]₄), ruthenium acetylacetonate (Ru(acac)₃), iridium acetylacetonate (Ir(acac)₃), tin(II) acetylacetonate (Sn(acac)₂), tin(IV) isopropoxide (Sn[OCH(CH₃)₂]₄), platinum acetylacetonate (Pt(acac)₂), and the like.

### Examples

### Example 1: Free-Standing Epitaxial SrTiO₃ Nanomembranes Via Remote Epitaxy Using Hybrid

### Molecular Beam Epitaxy

In conventional epitaxial growth, the epilayer is intimately linked to the substrate. This reality prevents the reuse of the expensive single-crystal substrate, unless the film is to be sacrificed by polishing it away. Furthermore, permanently joining the film and substrate can generate challenges in characterizing a film due to signals from the substrate that are often many orders of magnitude stronger than those of the film. Therefore, there is both an economic and scientific impetus to develop facile methods of producing free-standing single-crystal nanomembranes.

The most rudimentary route is grinding or etching bulk wafers down to microscopic thicknesses. But this approach lacks precision and achieves poor material utilization, because a majority of the wafer is sacrificed. A more precise technique uses a sacrificial layer between the substrate and film which, upon removal, releases the thin film as a free-standing membrane. The sacrificial layer may be selectively melted or etched away. In systems where the target film preferentially absorbs light, the film region adjacent to the transparent substrate can be selectively vaporized with intense laser light, thus becoming the sacrificial layer. Using a sacrificial layer can offer the advantage of optionally reusing expensive substrates and has all the precision of the utilized thin-film growth technique. This approach has enabled new studies that are possible only with free-standing membranes, including straining thin films beyond levels possible with conventional biaxial strain and the creation of Moiré twist heterostructures.

Another strategy for achieving free-standing single-crystalline membranes is to utilize an interface with weak adhesion, such as by utilizing one or more van der Waals materials. The technique takes on different names depending on the crystalline orientation. When the film is oriented to the van der Waals material, it is called van der Waals epitaxy. If the film is oriented to the underlying substrate, the technique is called remote epitaxy. It is argued that the film nucleates on top of the van der Waals material and is oriented by the interatomic potential from the substrate penetrating through the van der Waals material. However, the underlying mechanism is still under debate due to the possibility of epitaxial lateral overgrowth through micro/nano holes in the van der Waals material. In practice, distinguishing these two mechanisms is challenging and has been a topic of significant current interest. However, there is no doubt that the use of a van der Waals material is nonetheless a proven method to obtain free-standing single-crystal membranes that has the advantages of high material utilization (no sacrificial layer required), optional substrate reuse, and/or the ability to obtain thin films with better crystal quality than in traditional epitaxy.

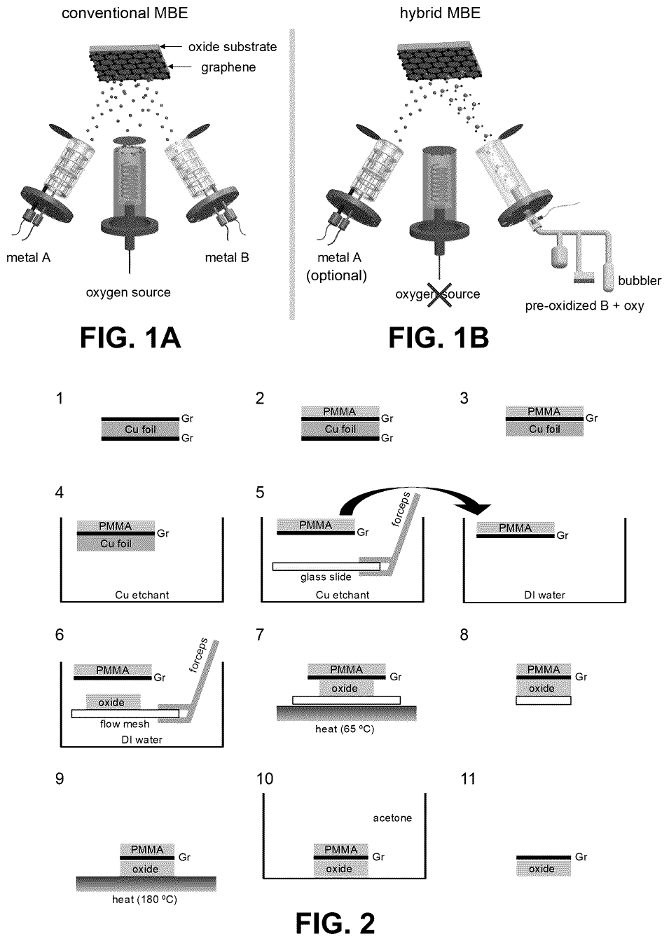

Given the chemical flexibility and functional diversity of the perovskite oxide material family, extension of remote epitaxy to perovskite oxides could provide a method to potentially improve structural quality and to study free-standing membranes. Oxide molecular beam epitaxy (MBE) is a highly modular and adaptable low-energy deposition technique that has been used to grow a wide range of perovskite oxides. Conventional oxide MBE uses effusion cells to sublime or evaporate metals (including metal suboxides) in conjunction with an oxygen source to oxidize the metals at the growth front, as shown in FIG. 1A. The oxygen source is often activated with an inductively coupled radio frequency (RF) or electron cyclotron resonance (ECR) microwave plasma, or it may be dilute or distilled ozone. Since these aggressive oxygen sources can decompose graphene, molecular oxygen supplied at a low background pressure of 7×10⁻⁷ Torr has been used as a more gentle source for remote epitaxy of oxides. However, it has not been possible to grow nano-membranes of complex oxides with self-regulating stoichiometry. For instance, SrTiO₃ films grown using conventional MBE (without an adsorption-controlled growth) would require precise flux control, which is typically no better than 0.1%, potentially resulting in a defect density as high as 10¹⁹ cm⁻³.

Hybrid MBE was employed to address these problems by replacing the elemental Ti with a titanium tetraisopropoxide (TTIP) metal-organic source. The high vapor pressure of TTIP or its decomposition intermediates provides a desorption mechanism that self-regulates the Sr:Ti cation stoichiometry and provides a growth window within which the incorporated Sr:Ti ratio is unity and is impervious to flux instabilities. Use of this technique can provide mobilities in SrTiO₃ films exceeding 120,000 cm²V⁻¹s⁻¹ using uniaxial strain, suggesting exciting opportunities for tunable electronic properties using membrane engineering.

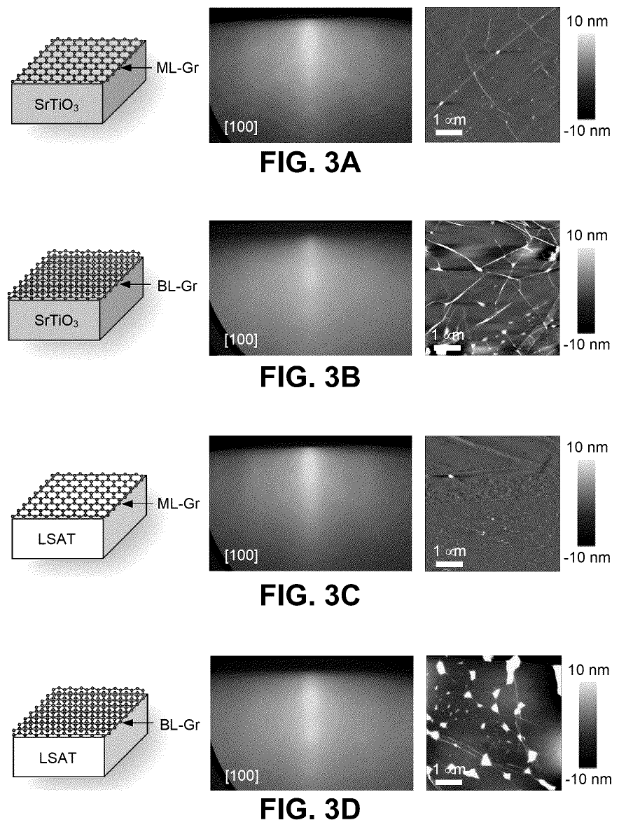

As described herein, hybrid MBE was employed with the oxygen source turned off to avoid graphene damage, as shown in FIG. 1B. The four oxygen atoms in each TTIP molecule provide sufficient oxygen to obtain phase-pure SrTiO₃. Even without the use of additional oxygen, an adsorption-controlled growth is achievable, a key feature leading to hybrid MBE's high material quality. This aspect of hybrid MBE can avoid graphene oxidation, while allowing exfoliation and transfer of the epilayer to remote substrates. In contrast to prior reports of oxide remote epitaxy using dry-transfer graphene, our approach yielded epitaxial SrTiO₃ films on wet-transferred graphene (see FIG. 2 and FIG. 3A-3D).

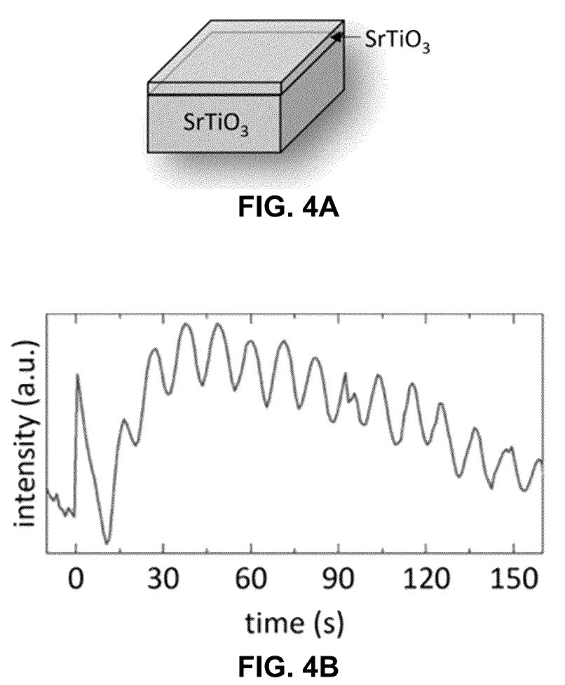

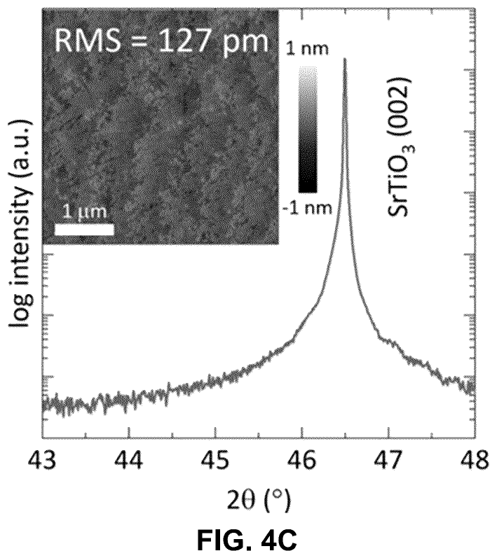

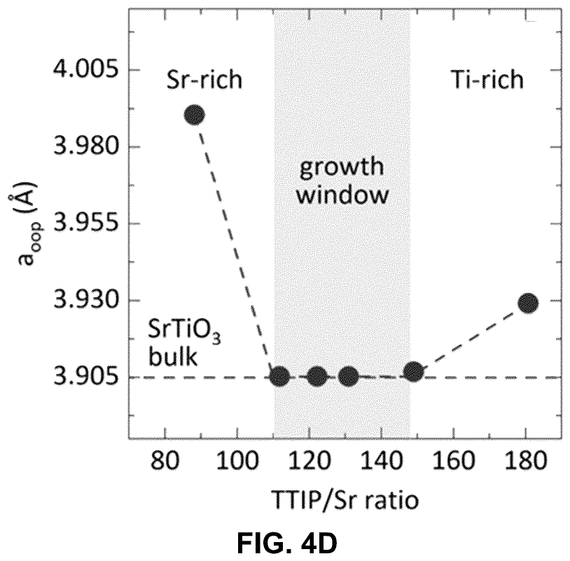

FIG. 4A-4D shows the results of applying this technique to homoepitaxial SrTiO₃ (without graphene). The clear reflection high-energy electron diffraction (RHEED) oscillations (FIG. 4B) and atomically smooth surfaces visible from atomic force microscopy (AFM, FIG. 4C inset) show that this technique results in atomic precision even without the use of an independent oxygen source. Through high-resolution X-ray diffraction (HRXRD), a lattice parameter that is indistinguishable from the substrate (FIG. 4C) and a wide MBE growth window (FIG. 4D) indicate that this modified technique also achieves adsorption-controlled growth with excellent structural quality and reproducibility.

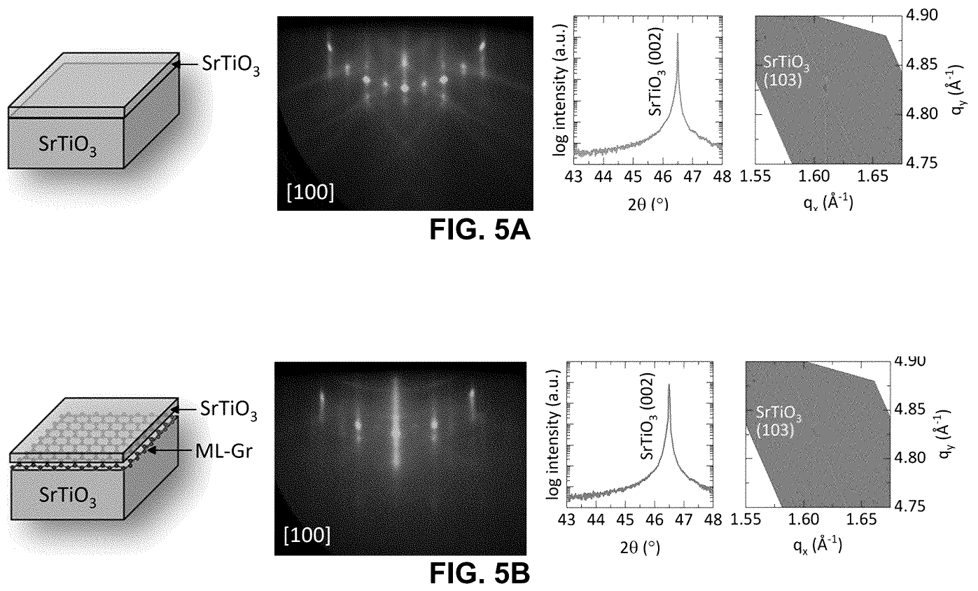

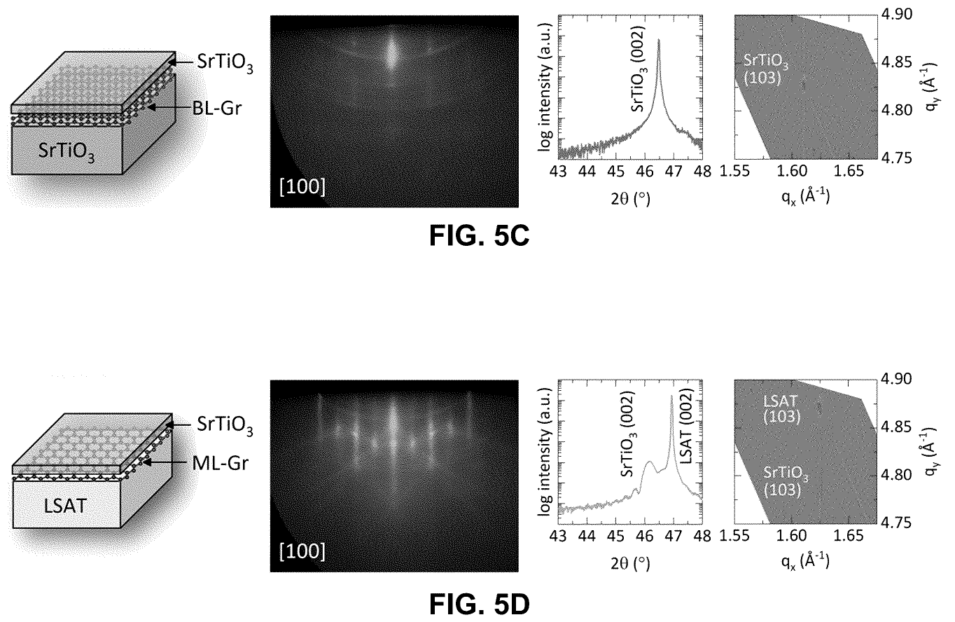

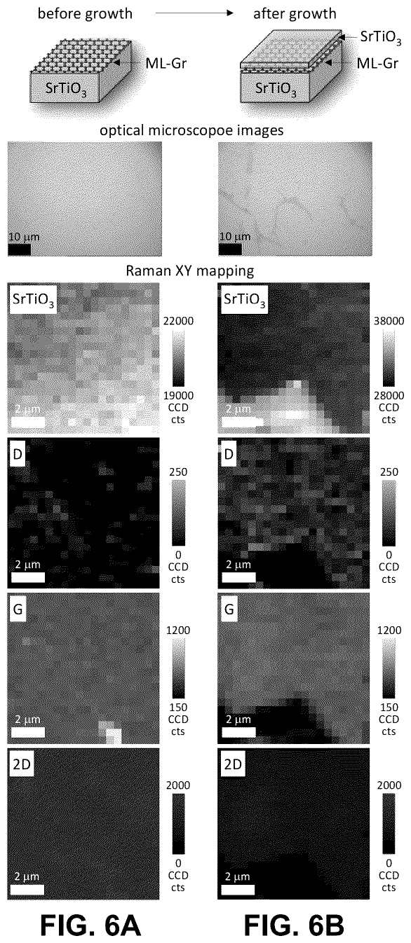

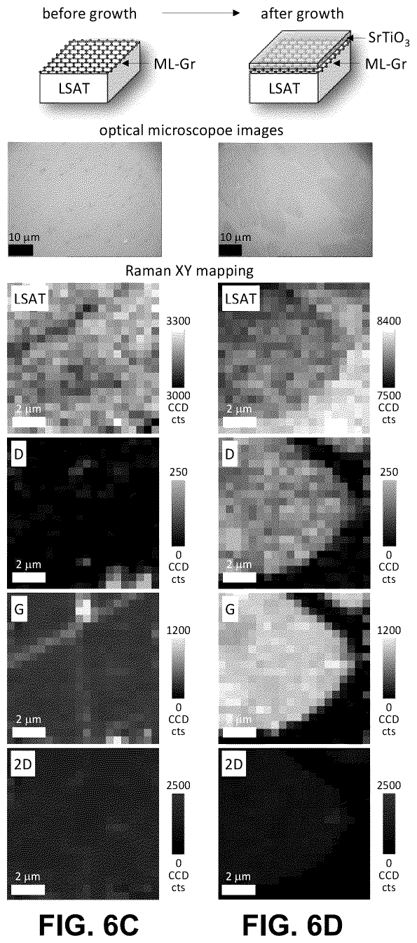

FIG. 5A-5D shows results from the growth of SrTiO₃ on bare SrTiO₃ substrates (FIG. 5A) as well as on SrTiO₃ substrates covered with monolayer graphene (FIG. 5B), bilayer graphene (FIG. 5C), and on LSAT [(La_{0.8}Sr_{0.82})(Al_{0.59}Ta_{0.41})O₃] substrates covered with monolayer graphene (FIG. 5D). The RHEED patterns for films grown on bare substrates and on monolayer graphene show half-order streaks and Kikuchi lines characteristic of high-quality epitaxial SrTiO₃, but the RHEED pattern on bilayer graphene is distinct. Using scanning transmission electron microscopy (STEM), ring-like pattern in RHEED images may likely be associated with the in-plane rotation of SrTiO₃ film owing to poor graphene quality underneath. Visible cracks were observed in the sample with the monolayer graphene after SrTiO₃ growth, whereas no cracks were found in the bilayer graphene sample (FIG. 6A-6D). Although the origin of these cracks is not well-understood and without wishing to be limited by mechanism, their formation may be associated with the poor quality of “wet-transferred” graphene and/or the presence of PMMA residue.

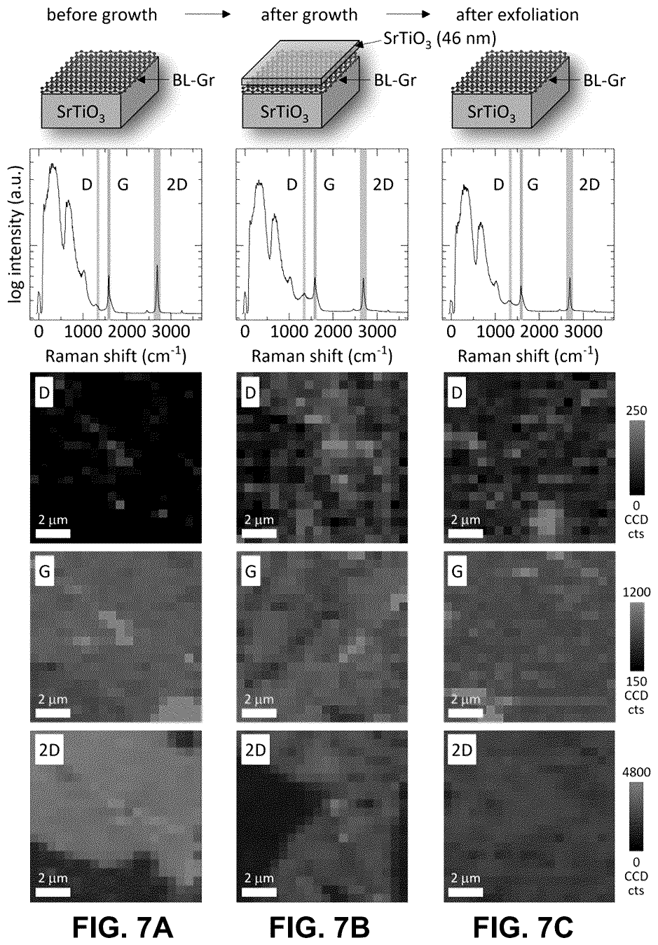

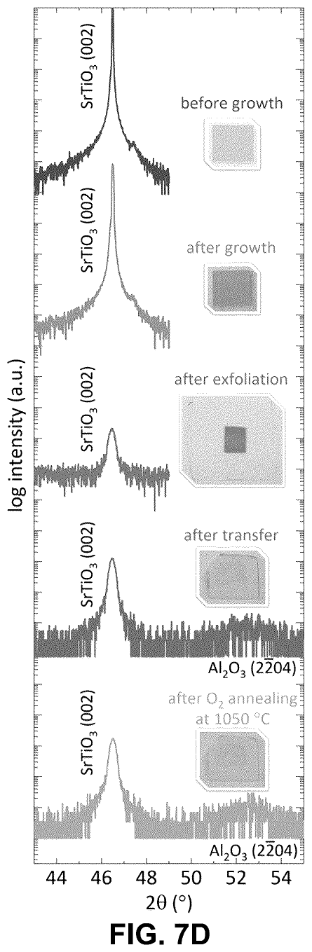

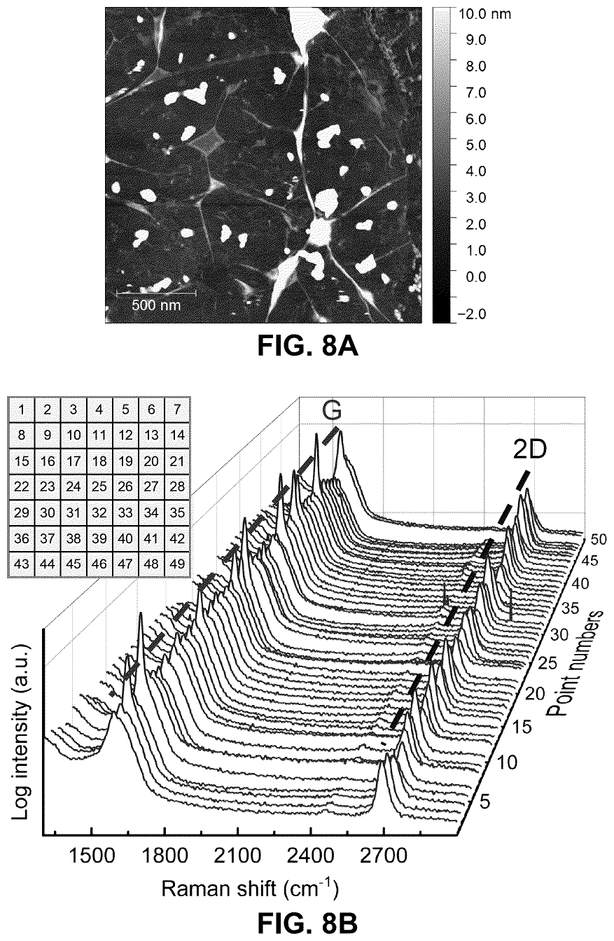

These results however raise the question of whether the graphene remained intact or whether graphene decomposed during growth. FIG. 7A-B addresses this question with confocal Raman spectroscopy before and after growth of 46 nm SrTiO₃ on bilayer graphene. Although the graphene D peak overlaps with a peak from SrTiO₃, the similar positions and intensities of the graphene G and 2D peaks before and after growth indicate that the graphene remains intact and undamaged during growth. In addition, FIG. 7C shows that film exfoliation leaves behind graphene on the substrate. Further analysis using Raman mapping reveals that graphene remains present on the entire surface (FIG. 8A-8B). This behavior should allow the substrate to be directly reused for growth of more epitaxial membranes. It is not clear why the SrTiO₃ film exfoliated at the film/graphene interface and not at the graphene/substrate interface. Without wishing to be limited by mechanism, it is likely due to the difference in interfacial energy when graphene is placed on SrTiO₃ versus when SrTiO₃ is grown on graphene.

Finally, FIG. 7D shows that the film can be exfoliated and transferred to other substrates, as revealed by the presence of the SrTiO₃ (002) peak throughout the entire transfer process. The step-by-step description of the exfoliation/transfer process is described in FIG. 9.

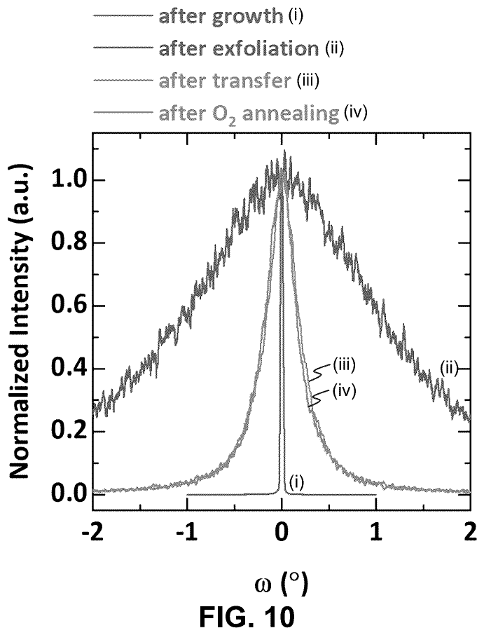

To investigate the structural quality of the film, rocking curve scans were performed of the SrTiO₃ (002) peak at each step of the transfer process. These results are provided in FIG. 10. First, after SrTiO₃ growth on bilayer graphene, the rocking curve of the film and the substrate overlapped, yielding a narrow rocking curve (line labeled as “(i)”, FWHM=0.032°). After exfoliation, the rocking curve became broad which is likely due to the Kapton tape's microscopically rough surface (line labeled as “(ii)”, FWHM=2.388°). However, after transferring the exfoliated SrTiO₃ film onto the r-Al₂O₃ substrate, the rocking curve became narrow again due to the atomically smooth surface of the r-Al₂O₃ substrate (line labeled as “(iii)”, FWHM=0.415°). The SrTiO₃ film transferred onto the r-Al₂O₃ substrate was annealed at 1050° C. for 3 minutes under an excess of oxygen gas using rapid thermal annealing. Its rocking curve became only slightly narrower (line labeled as “(iv)”, FWHM=0.372°). These results show that the SrTiO₃ film grown on bilayer graphene had good crystalline quality rivaling that of the bulk SrTiO₃ substrate. Without wishing to be limited by mechanism, the increase in the rocking curve's FWHM after the exfoliation and transfer processes is likely due to defects resulting from exfoliation and transfer.

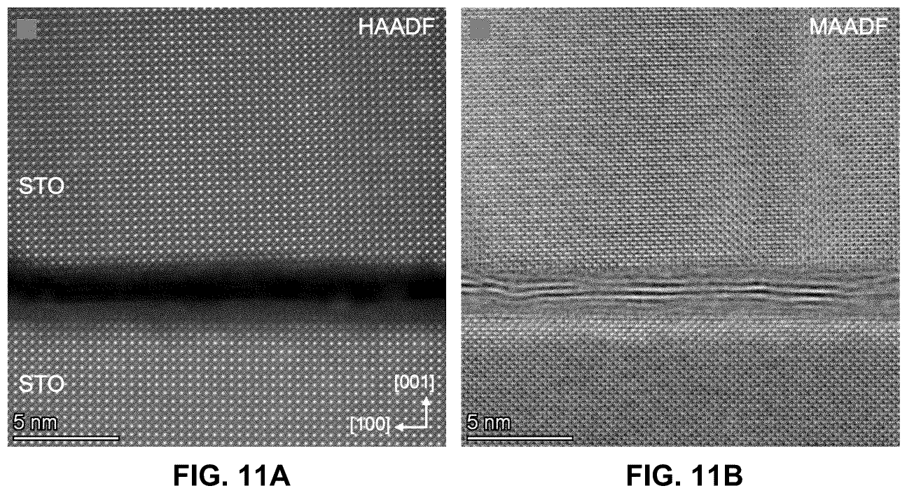

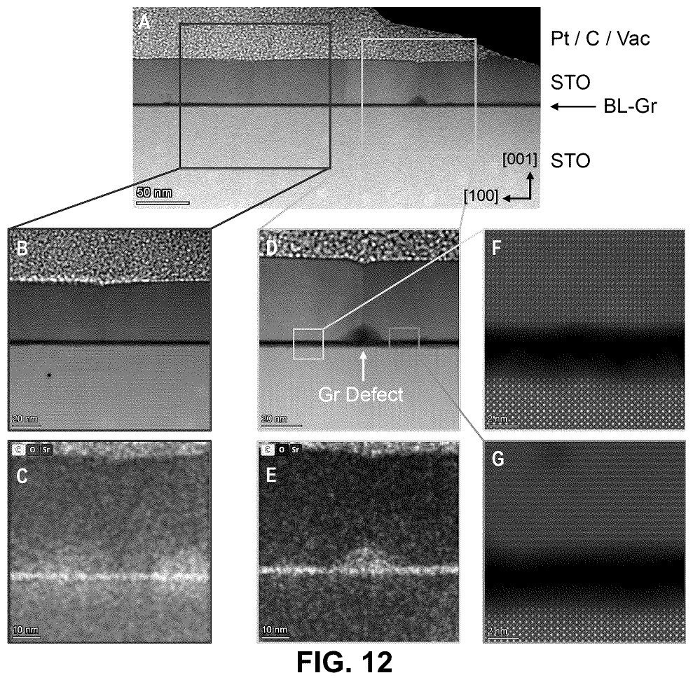

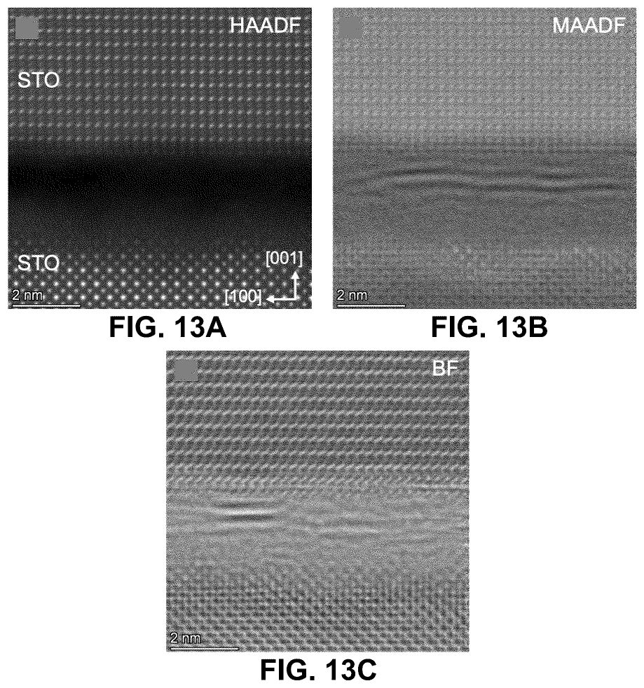

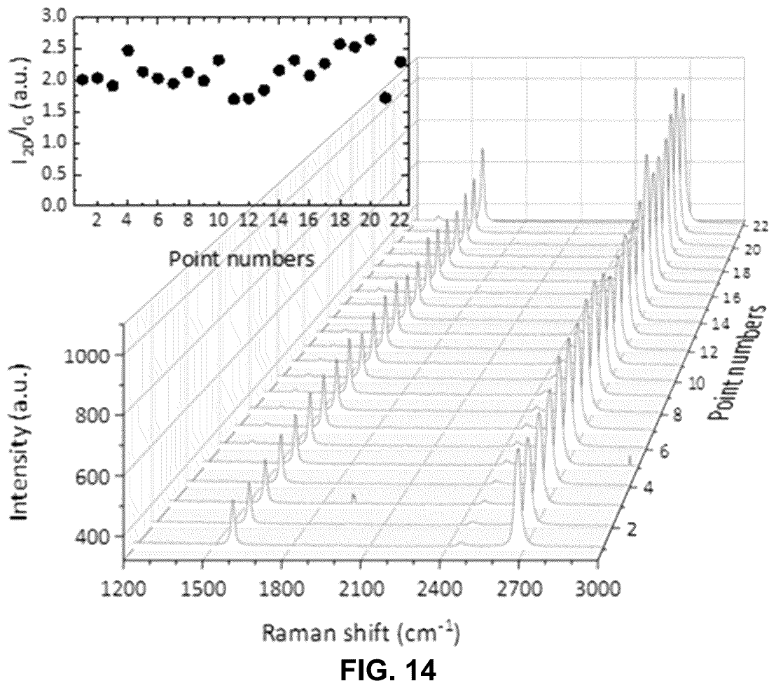

To directly image the structure, scanning transmission electron microscopy high-angle annular dark field (STEM-HAADF) imaging and energy-dispersive X-ray spectroscopy (STEM-EDS) elemental mapping were performed of the as-grown film prior to exfoliation and transfer. Consistent with the above observations, high-resolution HAADF STEM image (FIG. 11A) further confirms cube-on-cube epitaxy. In FIG. 12, a large continuous region of epitaxial film containing a graphene defect was observed. Specifically, an in-plane rotation was observed around the defect with an apparent [110] (001)//[100] (001) orientation relationship on one side of defect as shown in FIG. 12 (panels labeled as “F” and “G), with the medium-angle annular dark field (MAADF) and bright-field imaging in FIG. 13B-C. About 3-4 layers of graphene are preserved, with an approximate ˜3.8 Å inter-layer spacing. Without wishing to be limited by mechanism, this graphene defect is likely the residual PMMA that was left despite the cleaning process (the details of the cleaning process are presented in Example 2 herein) or graphene “bunched” into faceted piles. These defects can be present in wet-transferred graphene. It is therefore conceivable that these piles perturb the film growth, leading to the formation of domain boundaries at the pile apex and associated in-plane lattice rotation, likely resulting from local strain variations. FIG. 14 further shows that the graphene thickness is largely uniform based on the method using G/2D peak intensity ratio (35) and, therefore, is likely not responsible for in-plane rotation. As shown in FIG. 12 (panels labeled as “F” and “G), carbon bunching results in large regions of ordered, on-zone domains interspersed with slightly rotated domains, which are nonetheless epitaxial out-of-plane. Taken together, these results attest to the compatibility of graphene with the hybrid MBE technique for complex oxide growth. A larger graphene thickness in STEM is likely due to graphene folding or oxidation during STEM specimen preparation e.g. during the ion beam milling step.

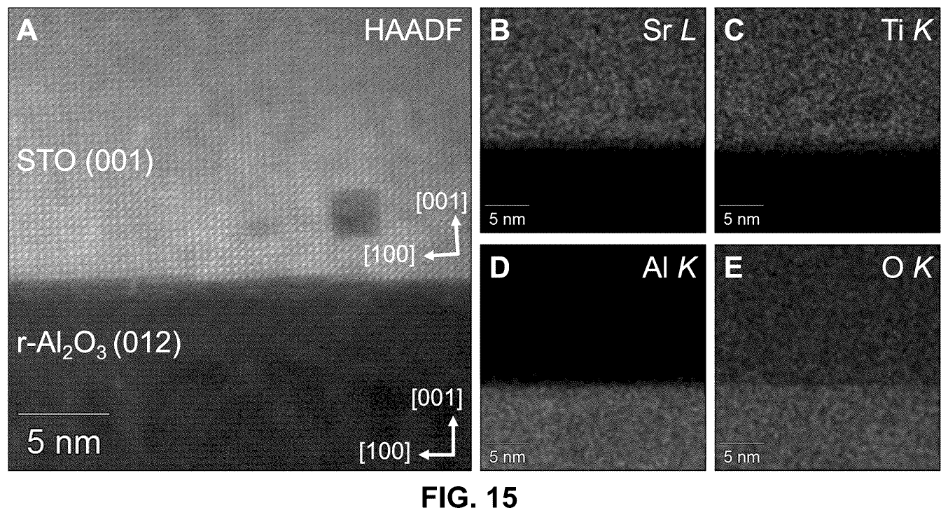

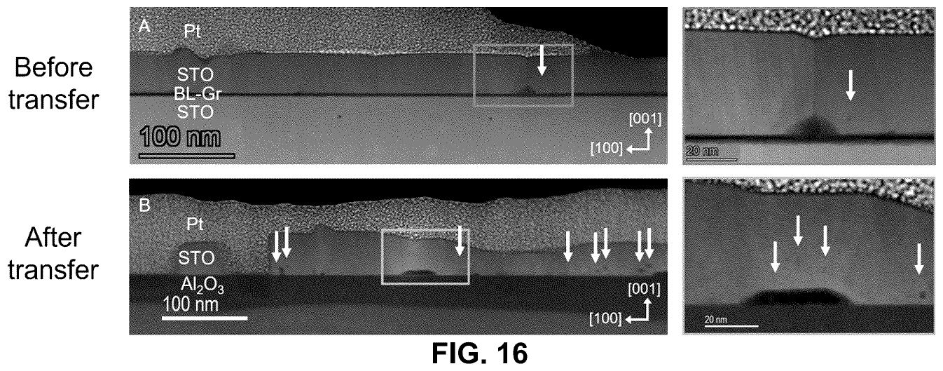

Finally, FIG. 15 shows STEM-HAADF and STEM-EDS composition maps of the transferred film after annealing (FIG. 7D, after O₂ annealing at 1050° C.). These data again reveal epitaxial, single-phase film on a foreign substrate (r-Al₂O₃) confirming the successful transfer of an epitaxial SrTiO₃ film. This result is consistent with the X-ray diffraction data in FIG. 7D. FIG. 16 shows wide field of view STEM-HAADF images of films before and after transfer (panels labeled as “A” and “B,” respectively) showing defects similar to the partial square hole (void) visible in FIG. 15 (panel labeled as “A”). Due to the highly local nature of STEM analysis, the understanding of how prevalent these defects are in these films is limited; nonetheless, the linear density of defects appears much lower in the as-grown film (1 defect over 500 nm) than in the film after transfer (8-10 defects over 500 nm). Consistent with the broadening of FWHM in rocking curve, these results suggest that source of these defects is likely the exfoliation/transfer/annealing process.

In summary, described herein is a hybrid MBE approach for growing epitaxial films of SrTiO₃ on graphene using Sr and TTIP sources without the use of an additional oxygen source. The technique produces films with atomic thickness control and self-regulated cation stoichiometry within a growth window. The films can be exfoliated as free-standing membranes and transferred to other substrates. This study encompasses a wide range of studies on free-standing oxide membranes with the benefits afforded by hybrid MBE. Such studies can also include approaches for improving the quality of these films with dry-transferred or in-situ-grown graphene. In addition, a wider variety of material systems and heterostructures can be investigated. However, the fact that the use of wet-transferred graphene also supports the epitaxial growth clearly suggests the robustness of remote epitaxy process adding to its versatile nature.

### Example 2: Non-Limiting Materials and Methods

### Graphene Growth and Transfer

Graphene was grown on both sides of polycrystalline copper foil using chemical vapor deposition in a quartz tube furnace. First, the foil was hydrogen-annealed in 16 standard cubic centimeters per minute (sccm) of hydrogen at 30 mTorr, while the furnace ramped to the growth temperature of 1050° C. (˜20 minutes). Then, the foil was annealed for another 30 minutes at the growth temperature under the same flow and pressure. To grow graphene, 21 sccm hydrogen and 0.105 sccm methane were supplied, while the furnace was maintained at 250 mTorr for 30 minutes. These conditions create self-terminating growth of one graphene monolayer. Then, the methane flow was stopped, and the hydrogen flow set to 16 sccm while the furnace cooled off (˜3 hours).

A solution of 4 wt % polymethylmethacrylate with a molecular weight of 950,000 atomic mass units dissolved in chlorobenzene (PMMA 950 C4, MicroChem Corp., now Kayaku Advanced Materials, Inc., Newton, MA) was used for spin-coating. Then, graphene was removed from the bottom side of the copper foil with a 10-second exposure to oxygen plasma in a reactive ion etcher. Ammonium persulfate solution (7 g of (NH₄)₂S₂O₈ in 1 L of DI water) was used as a copper etchant to etch away the copper foil. Next, the remaining graphene was scooped and moved to deionized (DI) water for cleaning. Then, the cleaned graphene was scooped onto the target substrate using a flow-mesh. After transferring the graphene to the substrate, it was baked for 15 minutes. The baked sample was submerged in acetone for 48 hours and rinsed in fresh acetone and isopropyl alcohol to remove the PMMA residue. FIG. 2 shows a non-limiting step-by-step guide for graphene growth and transfer process.

### SrTiO₃ Epitaxial Film Growth

All films were grown using an oxide MBE (Scienta Omicron, Uppsala, Sweden) on 5 mm×5 mm substrates of single-crystal SrTiO₃ (001) or LSAT (001) with and without a graphene layer. During growth, the substrates were maintained at a thermocouple reading of 900° C. using a SiC-filament substrate heater. Strontium was supplied by thermal sublimation of distilled Sr dendrites (99.99% pure, Sigma-Aldrich, St. Louis, MO). Titanium and oxygen were supplied by the chemical precursor TTIP (99.999% pure, Sigma-Aldrich), which was fed to a line-of-sight gas injector (E-Science, Inc., Hudson, WI) via a custom gas inlet system using a linear leak valve and a Baratron capacitance manometer (MKS Instruments, Inc., Andover, MA) in a PID feedback loop to control the TTIP flow entering the chamber. Immediately after the substrate temperature setpoint reached idle, the RHEED pattern was collected in the same chamber where growth took place. FIG. 9 shows a non-limiting step-by-step guide for membrane exfoliation and transfer process.

### Characterization

The sample surface topography was measured by a Bruker Nanoscope V Multimode 8 atomic force microscopy (AFM) in contact mode. All X-ray diffraction was performed with a Rigaku SmartLab XE diffractometer. Reciprocal space maps were collected with the HyPix-3000 detector in 1-dimensional mode to simultaneously resolve 2θ while ω was scanned. Confocal Raman data were collected with a Witec Alpha 300 R confocal Raman microscope. The 532 nm source light was generated by a frequency-doubled Nd:YAG laser, and the output was analyzed with a diffraction grating spectrometer and CCD detector.

Cross-sectional STEM samples were prepared using a FEI Helios NanoLab DualBeam Ga⁺ Focused Ion Beam (FIB) microscope with a standard lift out procedure. STEM images were acquired on a probe-corrected Thermo Fisher Themis Z microscope operating at 300 kV, with a convergence semi-angle of 25.2 mrad and an approximate collection angle range of 65-200 mrad, 16-62 mrad, and 8-14 mrad for STEM-HAADF, STEM-MAADF, and low-angle annular dark field (STEM-LAADF), respectively. The STEM energy-dispersive X-ray spectroscopy (STEM-EDS) composition maps shown in FIG. 12 were acquired using a SuperX detector. The STEM-HAADF image shown in FIG. 15 was acquired on a probe-corrected JEOL GrandARM-300F microscope operating at 300 kV, with a convergence semi-angle of 29.7 mrad and a collection angle range of 75-515 mrad. The STEM-EDS composition maps shown in FIG. 15 were acquired using dual JEOL Centurio silicon drift detector setup.

### Example 3: BaTiO₃ Film Grown on a Graphene Covered STO Substrate Using Hybrid Molecular Beam Epitaxy

To further confirm the use of the methods herein, barium titanate (BaTiO₃) films were prepared on a graphene material. In brief, graphene was prepared with the same condition for the SrTiO₃ growth. BaTiO₃ films were grown on 5 mm×5 mm substrates of single-crystal SrTiO₃ (001) with a graphene layer using the same MBE system as SrTiO₃ film. During growth, the substrates were maintained at a thermocouple reading of 950° C. using a SiC-filament substrate heater. Barium was supplied by thermal sublimation of distilled Ba dendrites (99.99% pure, Sigma-Aldrich, St. Louis, MO). Titanium and oxygen were supplied by the chemical precursor TTIP (99.999% pure, Sigma-Aldrich), which was fed to a line-of-sight gas injector (E-Science, Inc., Hudson, WI) via a custom gas inlet system using a linear leak valve and a Baratron capacitance manometer (MKS Instruments, Inc., Andover, MA) in a PID feedback loop to control the TTIP flow entering the chamber. Oxygen was supplied via a radio frequency (RF) plasma source at a pressure of 5×10⁻⁶ Torr, operating at 250 W.

The following process was conducted to exfoliate the BaTiO₃ film. A 20 nm Ti layer, an adhesion layer, was deposited by an e-beam evaporator. Subsequently, 80 nm of Ni was deposited in the same e-beam chamber. Then, an additional 600 nm Ni layer, a stressor layer, was deposited by DC sputtering. After depositing the Ni stressor layer, a thermal release tape was applied to the sample (Ni/Ti/BaTiO₃/graphene/oxide substrate), and the tape was gently pressed by a Q-tip. Finally, the thermal release tape was mechanically detached by tweezers, providing a BaTiO₃ membrane.

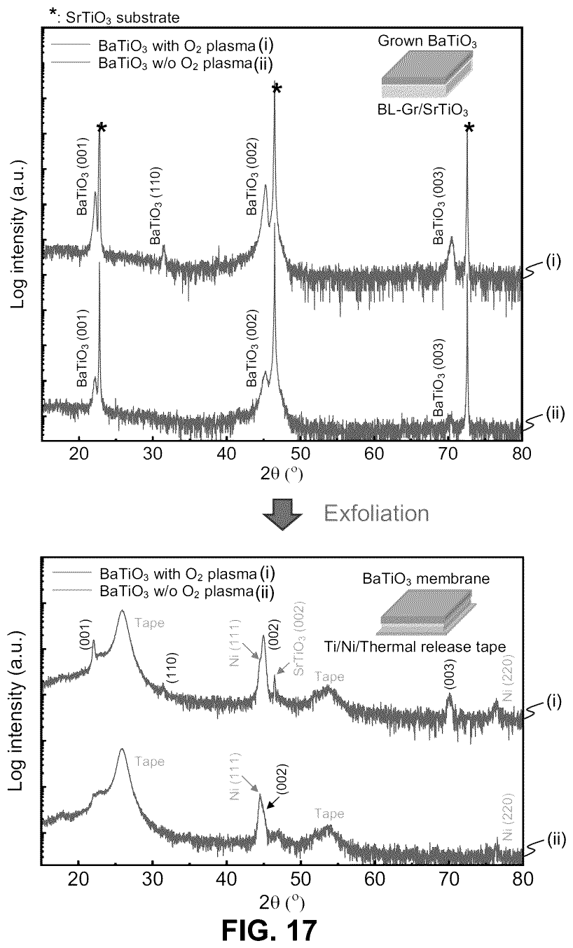

In particular, samples were prepared with and without oxygen plasma during deposition of the precursors. The films can be exfoliated as free-standing membranes and transferred to other substrates. As can be seen, FIG. 17 presents HRXRD 2θ-ω coupled scans of BaTiO₃ films grown with and without oxygen plasma before exfoliation (upper panel) and those after exfoliation (lower panel). Regardless of oxygen plasma presence during BaTiO₃ growth, (001)-oriented BaTiO₃ films were grown on graphene covered STO substrates and detached from the substrate by applying a stressor layer (thermal release tape/Ni/Ti). Specifically, highly ordered BaTiO₃ (001) film was observed under the oxygen plasma during growth, showing a stronger intensity of (001) peaks than that of (hh0) peaks. On the other hand, a single phase of BaTiO₃ (001) film was observed without oxygen plasma.

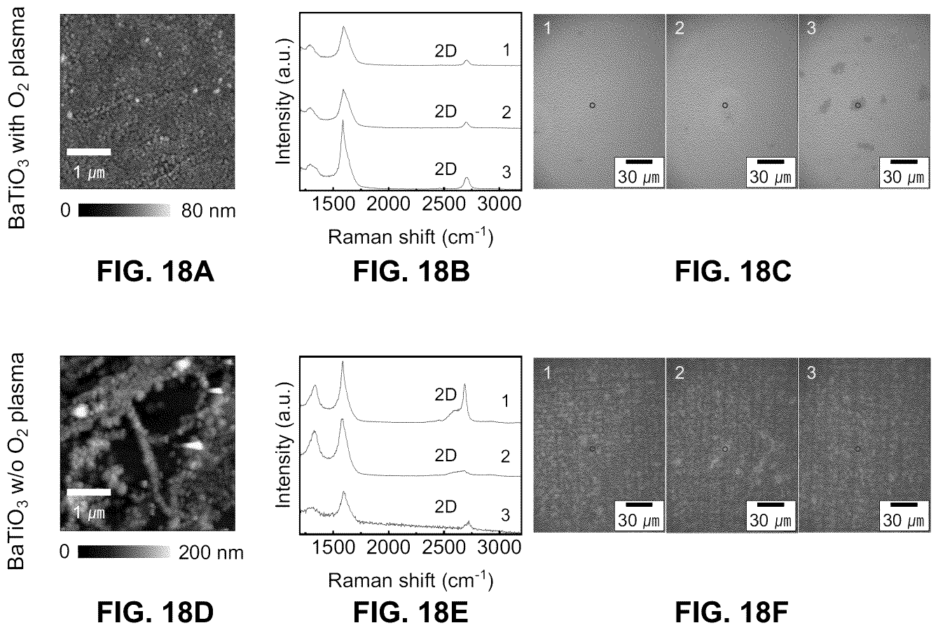

The surface morphology of the BaTiO₃ films grown with and without oxygen plasma was investigated by AFM (FIG. 18A, 18D). The BaTiO₃ islands were observed on both BaTiO₃ films, and discontinuity of the film is likely due to underlying graphene defects, such as wrinkles and bubbles that result from graphene wet transfer. Furthermore, the existence of the graphene layer was confirmed by Raman spectroscopy (FIG. 18B, 18E). The graphene 2D peak was observed at ˜2700 cm⁻¹ on the three arbitrary sites in each BaTiO₃ film (FIG. 18C, 18F), indicating that graphene is intact after BaTiO₃ growth even under oxygen plasma.

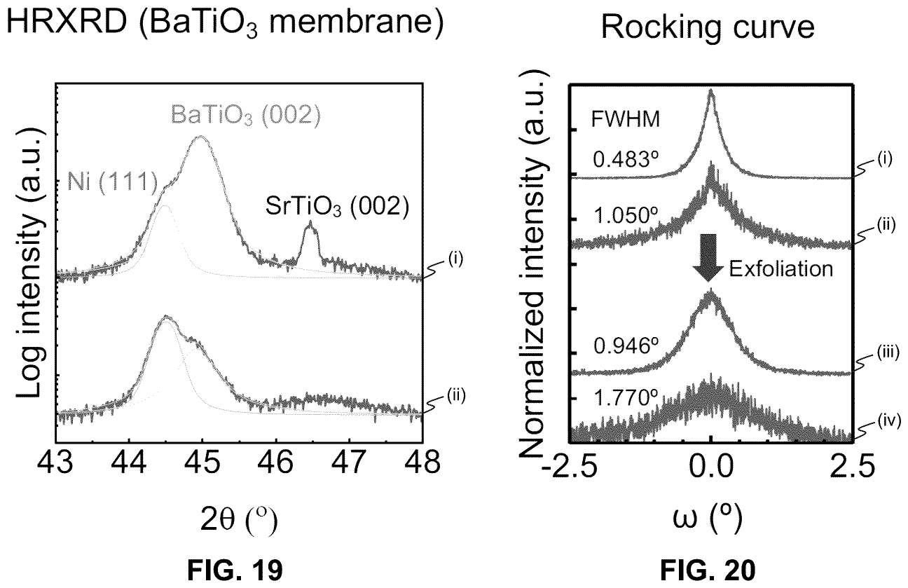

FIG. 19 shows HRXRD 2θ-ω coupled scans of the exfoliated BaTiO₃ films grown with and without oxygen plasma, focusing on the (002) peak. The BaTiO₃ (002) peak, located at ˜44.90°, was separated from the Ni (111) peak, indicating the availability of BaTiO₃ exfoliation from the substrate using a graphene layer.

Additionally, the structural properties of the film were investigated by rocking curves, as shown in FIG. 20. The FWHM of BaTiO₃ film grown was 0.483° with oxygen plasma and 1.0500 and without oxygen plasma. The different crystal qualities may come from the presence of oxygen plasma, but further study is required to find the origin. After exfoliation, the FWHM of the films was increased to 0.946° for the film with oxygen plasma and 1.7700 for the film without oxygen plasma, indicating lower crystal quality. The decrement in the crystal quality may be related to induced film damage during exfoliation or to misalignment during XRD measurement on the flexible stressor layer.

### OTHER EMBODIMENTS

It is to be understood that while the invention has been described in conjunction with the detailed description thereof, the foregoing description is intended to illustrate and not limit the scope of the invention, which is defined by the scope of the appended claims. Other aspects, advantages, and modifications are within the scope of the following claims.

What is claimed is:

1. A method of forming an oxide film, the method comprising:
providing a first substrate comprising a van der Waals material disposed on a top surface of said first substrate;
delivering a pre-oxidized precursor to a surface of said van der Waals material, wherein said pre-oxidized precursor comprises an organic moiety and one or more of an alkali metal, an alkaline earth metal, a transition metal, a post-transition metal, a metalloid, a lanthanide, or a combination of any of these, thereby forming said oxide film;
exfoliating said oxide film, or a portion thereof, from said van der Waals material and said first substrate; and
transferring the exfoliated oxide film, or a portion thereof, to a top surface of a second substrate.

2. The method of claim 1, wherein said first substrate comprises a single crystal substrate and/or an oxide substrate.

3. The method of claim 1, wherein said first substrate comprises strontium titanium oxide (STO) or lanthanum-strontium aluminum tantalate (LSAT).

4. The method of claim 1, wherein said van der Waals material comprises a monolayer or a multilayer.

5. The method of claim 4, wherein said van der Waals material comprises a monolayer of graphene or a bilayer of graphene.

6. The method of claim 4, wherein said van der Waals material comprises hexagonal boron nitride (h-BN), molybdenum disulfide (MoS₂), molybdenum diselenide (MoSe₂), tungsten disulfide (WS₂), or amorphous graphene.

7. The method of claim 1, wherein said delivering further comprises delivering a metal precursor with the pre-oxidized precursor, and wherein the metal precursor comprises an alkali metal, an alkaline earth metal, or a combination of any of these.

8. The method of claim 1, wherein said pre-oxidized precursor comprises a transition metal, a post-transition metal, a metalloid, a lanthanide, or a combination of any of these.

9. The method of claim 8, wherein said pre-oxidized precursor comprises a metal organic precursor.

10. The method of claim 9, wherein said pre-oxidized precursor further comprises at least one organic ligand of R or OR, and wherein R is an organic moiety.

11. The method of claim 1, wherein said delivering is conducted in the absence of an oxygen source.

12. The method of claim 1, wherein said delivering is conducted in the presence of plasma.

13. The method of claim 1, wherein said oxide film comprises a perovskite oxide.

14. The method of claim 1, wherein said oxide film comprises a thin film or a nanomembrane.

15. The method of claim 14, wherein said film or said nanomembrane comprises a thickness of about 1 nm to about 1 micron.

16. The method of claim 14, wherein said film or said nanomembrane comprises a single crystalline film or a film with high mobility, high dielectric constant, high thermal conductivity, ferroelectricity, multiferroicity, and/or superconductivity.

17. The method of claim 1, wherein said second substrate comprises an oxide substrate, a dielectric substrate, a flexible substrate, or a carrier substrate.

18. The method of claim 1, further comprising:
annealing the transferred oxide film, or a portion thereof.

19. A free-standing structure comprising:
an oxide film disposed on a top surface of a foreign substrate;
wherein said foreign substrate is similar or different than a substrate used to form the film, and
wherein said oxide film comprises one or more of an alkali metal, an alkaline earth metal, a transition metal, a post-transition metal, a metalloid, a lanthanide, or a combination of any of these.

20. The structure of claim 19 formed by the method of claim 1.
